(19) United States
(12) Patent Application Publication
(10) Pub. No.: US 2026/0114072 A1
(43) Pub. Date: Apr. 23, 2026

(54) BI-FACIAL SOLAR PANELS INCORPORATING SILICON FORMED ON A SUBSTRATE

(71) Applicant: Blue Origin, LLC, Kent, WA (US)

(72) Inventors: Jeong Chul Lee, Monrovia, CA (US); Alexander Imbault, Sierra Madre, CA (US); Eric D. Contreras, San Dimas, CA (US); Jonathan Grandidier, Pasadena, CA (US); Parthiv Daggolu, Reseda, CA (US)

(21) Appl. No.: 18/922,161

(22) Filed: Oct. 21, 2024

(51) Int. Cl. H01L 31/0288; H01L 31/0224; H01L 31/18

(52) U.S. Cl. CPC H10F 77/1223; H10F 71/121; H10F 77/215; H10F 77/219

(57) ABSTRACT

Systems and methods for fabricating a bi-facial solar cell are presented. Among many possible applications for a bi-facial solar cell described herein, a particularly interesting one is its application on the south pole region of the Moon. In this region, rather than rising and setting, the Sun travels in a complete circle, skimming low over the Moon's horizon. The bi-facial solar cell may be oriented vertically so that either one or the other side of the solar cell will be positioned to receive solar radiation to generate electricity. The bi-facial solar cell may include p-type regions adjacent to n-type regions on each side of the solar cell. The p-n junctions are between the p-type regions and the n-type regions and on or near the surface of each side of the solar cell.

### BACKGROUND

Fabrication of devices and processing of materials are generally energy-intensive operations. Most often, the form of energy is electricity. On Earth, there is an ever-increasing recognition that energy is a valuable resource to be conserved or used wisely. On the Moon, availability of energy, such as electricity for use in fabrication or material processing, is presently limited to Earth-derived resources (e.g., fuel cells, batteries, etc.). Thus, providing electricity for fabrication or material processing on the Moon may be challenging.

Solar panels have become relatively commonplace as a means for generating electricity via the sun. Solar panels may comprise photovoltaic solar modules that absorb sunlight as a source of energy to generate direct-current electricity. A photovoltaic module is a packaged, connected assembly of photovoltaic solar cells available in different voltages and wattages.

Solar cells have been, and continue to be, the main power source for most Earth orbiting satellites and various probes in the inner solar system since they provide a favorable power-to-weight ratio. Moreover, equipment and occupants in a space, lunar, or planetary environment have few other power options. Unfortunately, costs associated with bringing (e.g., launching) solar cells or panels into space from Earth are very high.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a schematic depiction of a bi-facial solar cell on or near the south pole of the Moon, according to some embodiments.

FIG. 2 is a perspective view of a bi-facial solar cell, according to some embodiments.

FIG. 3 is a schematic cross-section view of a bi-facial solar cell, according to some embodiments.

FIG. 4 is a schematic top or bottom view of a bi-facial solar cell, according to some embodiments.

FIG. 5 is a schematic cross-section view of a system for forming silicon sheets on a substrate for a bi-facial solar cell, according to some embodiments.

FIG. 6 is a flow diagram of a process for fabricating a bi-facial solar cell, according to some embodiments.

### DETAILED DESCRIPTION

This disclosure describes, among other things, systems and methods for fabricating a bi-facial solar cell. Among many possible applications for a bi-facial solar cell described herein, a particularly interesting one is its application on the south pole region of the Moon. As explained below, in this region, rather than rising and setting, the Sun travels in a complete circle, skimming low over the Moon's horizon. The bi-facial solar cell may be oriented vertically so that either one or the other side of the solar cell will be positioned to receive solar radiation to generate electricity.

A solar cell, or photovoltaic cell, is an electronic device that converts the energy of light directly into electricity by the photovoltaic effect. Electrical characteristics of the cell, such as current, voltage, and resistance, vary when exposed to light. Individual solar cell devices are often the electrical building blocks of photovoltaic modules, such as solar panels. The operation of a photovoltaic (solar) cell involves three basic attributes: 1) The absorption of light to generate excitons (bound electron-hole pairs), unbound electron-hole pairs (via excitons), or plasmons. 2) The separation of charge carriers of opposite types. 3) The extraction of those carriers to an external circuit.

Generally, solar cells may be p-type or n-type. The term p-type refers to the solar cell being built on a positively charged (p-type) silicon substrate. For example, the silicon substrate may be doped with boron (trivalent), which has one valence electron less than silicon (quadrivalent). In various embodiments, the top and bottom (e.g., for a bi-facial solar cell) of the silicon substrate may be negatively doped (n-type) with phosphorous (pentavalent), which has one valence electron more than silicon. The top and bottom of the substrate may also be positively doped (p-type). This arrangement on both sides (e.g., faces) of the substrate may form multiple p-n junctions that will enable the flow of electricity in a solar panel. Other elements may be used for doping in different embodiments.

The bi-facial solar cells described herein comprises multiple p-type and n-type regions that are adjacent to one another on both sides of the solar cell. Accordingly, a complete electrical circuit, including a positive terminal and a negative terminal may be provided by each of the two sides of the solar cell. This is in contrast to other types of solar cells having a positive terminal on one side of the solar cell and a negative terminal on the opposite side of the solar cell. For example, in these types of solar cells, p-type and n-type layers are stacked on top of each other, not side by side, as in embodiments described herein. Also, in these types of solar cells, the p-n junction is between the stacked p-type and n-type layers and is thus buried in the solar cell's structure, not at or near the surface of the solar cell (and not side by side with the p- and n-type regions), as in embodiments described herein.

For most types of solar cells, the junction between the p-type and n-type layers, however configured relative to each other, is important for the operation of the solar cell: when light strikes the solar cell, the light excites electrons across this junction, creating an electric current. A p-n junction is a boundary or interface between two types of semiconductor materials, p-type and n-type, inside crystalline silicon. As indicated above, the “p” (positive) side contains an excess of holes, while the “n” (negative) side contains an excess of electrons in the outer shells of the electrically neutral atoms. This allows electric current to pass through the junction only in one direction.

The p- and n-type regions creating the p-n junction are made by doping the semiconductor, for example by ion implantation, diffusion of dopants, or by epitaxy (e.g., growing a layer of crystal doped with one type of dopant on top of a layer of crystal doped with another type of dopant). When the p-n junction is first formed, due to the concentration gradient, mobile charges transfer near the junction. Electrons leave the n-type region and holes leave the p-type region. These mobile carriers become minority carriers in the new region. Recombination limits these mobile carriers to relatively short penetration distances out of this region. Due to charge transfer, a voltage difference occurs between regions. This creates a field at the junction that causes drift currents to oppose the diffusion current.

In various embodiments, a bi-facial solar cell includes a substrate having a first surface and a second surface opposite the first surface. Each of these surfaces is configured to be part of a solar cell. For example, a first silicon sheet is on the first surface and a second silicon sheet is on the second surface and each silicon sheet comprises both p-type regions and n-type regions. Herein, a silicon sheet is a layer of silicon that is deposited or formed onto a substrate by techniques described below. The p-type regions and the n-type regions are arranged side by side with one another. Electrical contacts on the p-type and the n-type regions are in each of the first and the second silicon sheets. The electrical contacts on each of the p-type regions and the n-type regions may include both conductive busbars and fingers. Accordingly, the structure and elements on one side (e.g., the first surface) of the substrate are substantially the same as those on the other side (e.g., the second surface) of the substrate. For example, the electrical contacts on the p-type regions and the n-type regions that are in each of the first and the second silicon sheets may comprise both a positive junction and a negative junction, respectively, for an external circuit. In other words, each side of the substrate may be configured to independently or accumulatively provide a source of solar-based power.

In some particular implementations, the substrate is iron-depleted lunar regolith, which may be an electrolyte of a molten electrolysis process. For example, regolith may be harvested from the lunar surface and iron oxide minerals, or elemental iron, may be separated out by any of a number of techniques, such as molten oxide electrolysis (MOE), molten regolith electrolysis (MRE), high-gradient magnetic separation, or flotation processes, for example. In some embodiments, regolith harvested from the lunar surface may be processed mechanically to separate out at least a substantial portion of iron bearing minerals. For instance, the iron-depleted lunar regolith may comprise less than about 0.5% iron content by weight, though claimed subject matter is not so limited. Other sources of material, if not lunar regolith, for a substrate of the bi-facial solar cell may be Earth-based or on various objects in the Solar System, such as asteroids, moons, minor-planets, and planets.

In some embodiments, the bi-facial solar cell further includes i) boron silicate glass on the p-type regions in each of the first and second silicon sheets and ii) phosphor silicate glass on the n-type regions in each of the first and the second silicon sheets. However, claimed subject matter is not limited to any particular material compositions, deposition methods, or post-treatment of silicon.

In various embodiments, a method for fabricating a bi-facial solar cell, such as that described above, may include physically supporting a substrate so that the substrate is at least partially submerged in molten silicon, controlling temperature and motion of the molten silicon with respect to the substrate so that a silicon sheet comprising a crystalline structure of the molten silicon forms on two opposing sides of the substrate, and drawing the substrate with the silicon sheets formed thereon upward out of the molten silicon. Such controlling of the temperature and the motion of the molten silicon may involve, among other things, maintaining the temperature of the molten silicon to be above the melting temperature of silicon and below a melting temperature of the substrate, and controlling a speed at which the substrate is drawn out of the molten silicon. The method may also include forming p-type regions and n-type regions in the silicon sheets on both of the two opposing sides of the substrate. The p-type regions and the n-type regions may be arranged side by side with one another on each of the silicon sheets. Forming the p-type regions and the n-type regions may involve forming boron silicate glass and phosphor silicate glass on the silicon sheets on both of the two opposing sides of the substrate and diffusing boron and phosphor dopants from the boron silicate glass and the phosphor silicate glass, respectively, into the silicon sheets.

The method may continue with forming electrical contacts on the p-type and the n-type regions that are in each of the silicon sheets. In some implementations, forming the electrical contacts on the p-type regions and the n-type regions may involve forming openings (e.g., via laser oblation or other technique) in the p-type regions and the n-type regions that are on each of the two opposing sides of the substrate and depositing a metal, such as aluminum, into the openings. As mentioned above, the electrical contacts on the p-type regions and the n-type regions on each of the two opposing sides of the substrate may comprise both a positive junction (e.g., positive voltage) and a negative junction (e.g., negative voltage) for an external circuit.

In some implementations, the two opposing sides of the substrate may be treated to increase their wettability with molten silicon, as described below. The method may be performed in the natural vacuum of the Moon. On Earth, however, an artificial vacuum may be provided for various parts of the method.

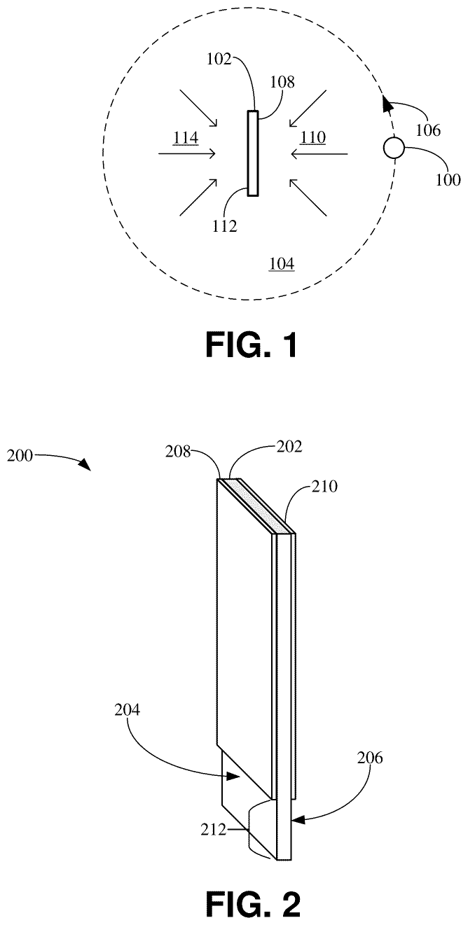

FIG. 1 is a schematic top-view depiction of the Sun 100 illuminating a bi-facial solar cell 102 placed on a surface 104 of the Moon that is at or near the south pole, according to some embodiments. In this region of the Moon, the Sun's movement, represented schematically by circle and arrow 106, is quite unique due to the Moon's rotation and its orbital position relative to the Earth and the Sun. For an observer (or solar cell 102), the Sun appears to glide around the horizon, as indicated by circle and arrow 106, never rising more than about 1.5 degrees above or below it. This creates a situation where the Sun seems to be skimming the horizon, making a full 360-degree circuit around the terrain. This results in the Sun being constantly low in the sky, producing extremely long shadows that rotate across the rugged lunar terrain. For a period of about two weeks, the Sun illuminates one side 108 of solar cell 102, as indicated by arrows 110. For a subsequent period of about two weeks, the Sun illuminates the other side 112 of solar cell 102, as indicated by arrows 114. Accordingly, bi-facial solar cell 102 is configured to receive solar illumination during substantially all parts of the Sun's motion.

FIG. 2 is a simplified perspective view of some parts of a bi-facial solar cell 200, according to various embodiments. Solar cell 200, which may be the same as or similar to solar cell 102, may comprise a substrate 202 having a first surface 204 and a second surface 206 opposite the first surface. Each of these surfaces may be configured to be a solar cell by the addition and/or treatment of various elements thereon. For example, a first silicon sheet 208 is on first surface 204 and a second silicon sheet 210 is on second surface 206. Not illustrated in this figure are p-type regions and n-type regions in each silicon sheet 208 and 210 and electrical contacts on the p-type and the n-type regions. In some implementations, a portion 212 of substrate 202 may (but need not) extend beyond first silicon sheet 208 and second silicon sheet 210 and function, at least in part, as a support structure for solar cell 200. For example, this part of the substrate, in addition to other structures, may be configured to support the bi-facial solar cell on the lunar surface. This is in contrast to other types of solar cells that use a silicon wafer as a substrate, which would likely not have the strength to support a structure such as a solar cell or solar panel. But in embodiments described herein, the substrate (e.g., 202) may be relatively strong because of the material it is made out of and also because of its thickness or other dimensions.

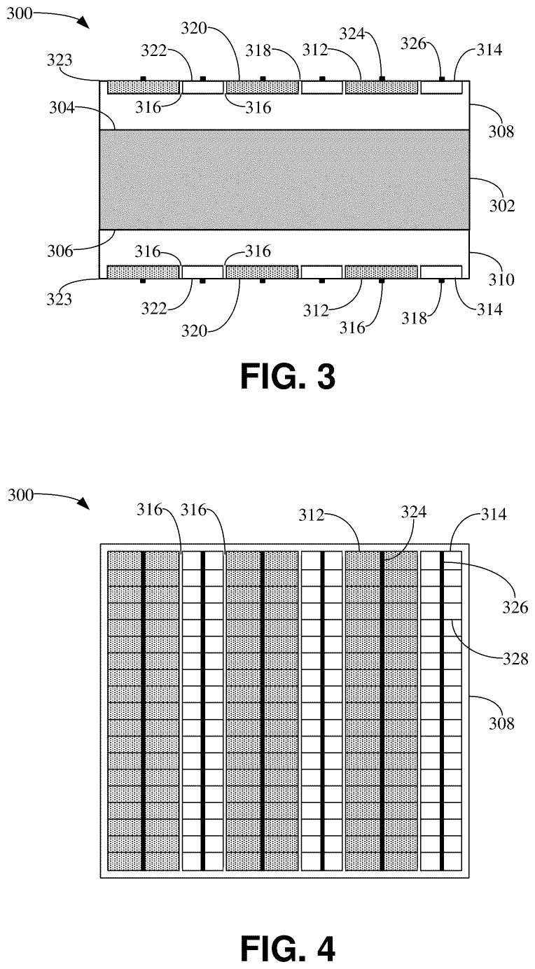

FIG. 3 is a schematic cross-section view and FIG. 4 is a schematic top or bottom view of a bi-facial solar cell 300, according to some embodiments. Dimensions of the various parts of solar cell 300 are not necessarily illustrated to scale. Also, because both sides of solar cell 300 are substantially identical, the schematic top view would be unchanged if it instead represented a bottom view of the solar cell. Solar cell 300, which may be the same as or similar to solar cell 102 or 200, may include a substrate 302 having a first surface 304 and a second surface 306 opposite the first surface. A first silicon sheet 308 is on the first surface and a second silicon sheet 310 is on the second surface and each silicon sheet comprises p-type regions 312 and n-type regions 314. Both silicon sheets may be single- or multi-crystalline. As illustrated, the p-type regions and the n-type regions are arranged side by side with one another.

In various implementations, p-n junctions 316 are between the p-type and the n-type regions. Top surfaces 318 of p-n junctions 316, top surfaces 320 of p-type regions 312, and top surfaces 322 of n-type regions 314 may share a common top (or bottom) surface 323 of solar cell 300 that is configured to be exposed to the sun. Generally, p-n junctions 316 separate the electron and hole carriers to create a voltage by separating light-generated electron-hole pairs via an internal electric field. Electrical contacts 324 on the p-type regions and electrical contacts 326 on the n-type regions, which are in (or on) each of the first and the second silicon sheets, may be configured to connect across this voltage. The electrical contacts on each of the p-type regions and the n-type regions may include both conductive busbars and fingers 328. All of electrical contacts 324 may be interconnected to one another and all of electrical contacts 326 may be interconnected to one another. Fingers 328 may be fine slender areas (e.g., to minimize optical shadowing) of metallization that collect current for delivery to the busbars (e.g., electrical contacts 324 and 326).

In some implementations, first and second silicon sheets 308 and 310 may be p-type. In other implementations, the first and second silicon sheets may be n-type, as described below. Each type may have inherent advantages. For example, p-type silicon is generally more resistant to radiation, which makes it suitable for space applications. However, p-type silicon may suffer from light-induced degradation, which can affect its performance over time. On the other hand, n-type silicon is more durable and has a longer lifespan. Unlike p-type, n-type silicon is not susceptible to light-induced degradation.

First and second silicon sheets 308 and 310 may be made into either a p-type or an n-type by doping. For example, p-type silicon may be created when group III elements like boron or gallium are used as the doping agent, though claimed subject matter is not limited to any particular material compositions or deposition methods, The addition of these elements causes the silicon to have an abundance of positive charge carriers (e.g., holes). In contrast, n-type silicon may be created when group V elements like phosphorus, arsenic, or antimony are used to dope the silicon. This gives the silicon an abundance of negative charge carriers (e.g., electrons).

In addition to a doping process to create silicon sheets 308 and 310 as either a p-type or an n-type, p-type regions 312 and n-type regions 314 may be created by forming boron silicate glass and phosphor silicate glass on the silicon sheets on both of the two opposing sides of substrate 302 and allowing boron and phosphor dopants to diffuse from the boron silicate glass and the phosphor silicate glass, respectively, into the silicon sheets. In detail, boron silicate glass is on p-type regions 312 in each of the first and second silicon sheets and phosphor silicate glass is on n-type regions 314 in each of the first and the second silicon sheets. Accordingly, if the silicon sheets are n-type, then n-type regions 314 are doped at a concentration that is substantially greater than the doping concentration of the silicon sheets. Similarly, if the silicon sheets are p-type, then p-type regions 312 are doped at a concentration that is substantially greater than the doping concentration of the silicon sheets.

As mentioned above, dimensions of the various parts of solar cell 300 are not necessarily illustrated to scale. For example, first and second silicon sheets 308 and 310 may have a thickness in a range of about 10 to 200 microns and substrate 302 may have a thickness that is in the order of millimeters or greater, though claimed subject matter is not limited to any of these example values. The thickness of substrate 302 may not be a critical design factor because the substrate may merely be providing support for growing the silicon sheets (e.g., 308 and 310), but enough thickness may be required to provide mechanical and thermal strength without substantial bending after high temperature silicon growing from the molten silicon. The required thickness may likely be different for different substrate sizes. For example, substrate thickness may be a few to about 10 millimeters for a silicon layer area of 100 mm×100 mm and 200 mm×200 mm.

In some implementations, though not illustrated, coverglass comprising a silicate may be placed on surfaces 323 of solar cell 300. Coverglass may generally increase the lifetime of a solar panel by protecting the underlying solar cells from high energy cosmic or solar particles. In particular embodiments, coverglass comprising transparent silicate may be formed from lunar in-situ resources.

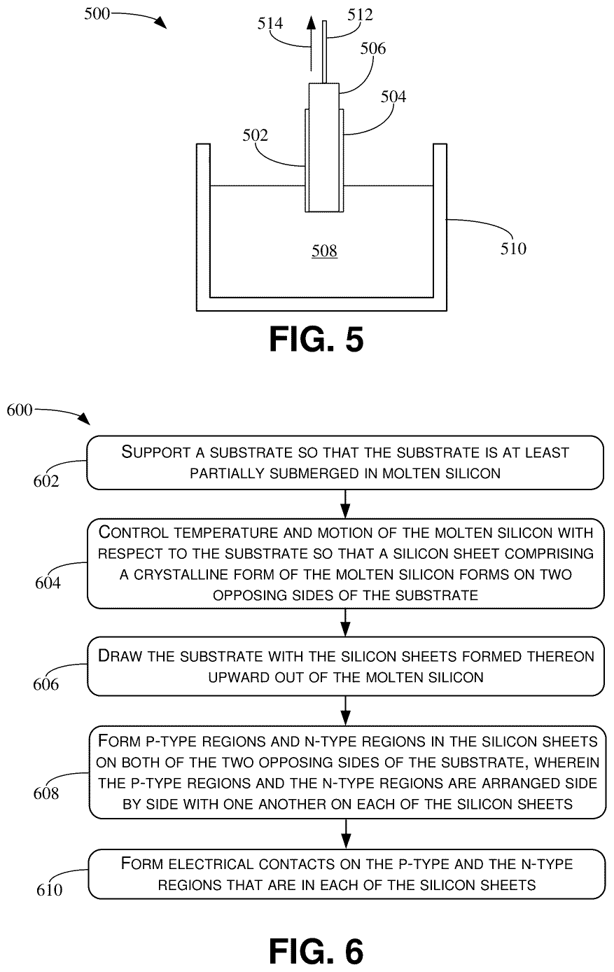

FIG. 5 is a schematic cross-section view of a system 500 for forming silicon sheets 502 and 504 on a substrate 506 for a bi-facial solar cell, according to some embodiments. The system, the formed silicon sheets, the substrate, and methods that use system 500 are fundamentally different from elements and fabrication methods of solar cells that incorporate a silicon wafer as a substrate. For example, in the latter type of solar cells, the silicon substrate acts as both a foundation and fabrication material that is doped for p-type and n-type regions. In contrast, the bi-facial solar cells described herein use a system, such as system 500, that involves a bath of molten silicon that is allowed to condense onto a substrate, such as substrate 506, that is a material other than silicon (though in some implementations the substrate may include at least relatively small amounts of silicon).

In some particular implementations, substrate 506 may be iron-depleted lunar regolith, which may be an electrolyte of a molten electrolysis process. FeOx (e.g., iron oxide, where x is an integer) is relatively abundant in lunar regolith. Thus, regolith harvested from the lunar surface may be processed so that iron oxide minerals, or elemental iron, may be separated out by any of a number of techniques, such as molten oxide electrolysis (MOE), molten regolith electrolysis (MRE), high-gradient magnetic separation, or flotation processes, for example. In some embodiments, regolith harvested from the lunar surface may be processed mechanically to separate out at least a substantial portion of iron bearing minerals. For instance, the iron-depleted lunar regolith may comprise less than about 0.5% iron content by weight, though claimed subject matter is not so limited. Other sources of material, if not lunar regolith, for a substrate of the bi-facial solar cell may be Earth-based or on various objects in the Solar System, such as asteroids, moons, minor-planets, and planets. FeOx is also relatively abundant on Earth, so there may be circumstances where Earth-bound solar cell fabrication would likewise involve removing iron oxide before extracting material to be used for substrate 506. Because iron can generally affect electrical properties of a material, it may be beneficial to reduce or eliminate the concentration of iron in the substrate to improve the performance of the solar cell. But iron removal or depletion of the substrate (e.g., 506) is not necessary in some implementations, and claimed subject matter is not limited in this respect.

In various embodiments, using system 500, a method for fabricating a bi-facial solar cell, such as solar cell 102, 200, or 300 described above, may include supporting substrate 506 so that the substrate is at least partially submerged in molten silicon 508. Generally, molten silicon may be contained in a refractory material-based vessel 510. The method may further include controlling the temperature of molten silicon 508 with respect to the substrate temperature. An important consideration for such temperature control is to keep the molten silicon temperature below the melting temperature of substrate 506 so that the substrate maintains its physical integrity so as to resist deformation, disintegration, or melting. Thus, controlling the temperature of the molten silicon may involve, among other things, maintaining the temperature of the molten silicon to be above the melting temperature of silicon but below a melting temperature of the substrate.

The motion of the molten silicon with respect to the substrate may also be controlled so that silicon sheets 502 and 504 may form as crystalline sheets of silicon, as opposed to amorphous silicon sheets. One consideration for controlling the motion of the molten silicon is that the silicon sheets are more likely to form as uniform crystalline sheets of silicon if convective currents or other fluid motions of the molten silicon are avoided. Another consideration for controlling the motion of the molten silicon relative to the substrate is that the silicon sheets are also more likely to form as uniform crystalline sheets of silicon if the substrate is drawn upward out of the molten silicon at a relatively slow and steady rate. In system 500, for example, substrate 506 may be supported by a support member 512 that is configured to draw the substrate out of molten silicon 508, as indicated by arrow 514. Support member 512 may be manually or automatically controlled to maintain a slow and steady rate of pulling substrate 506 out the molten silicon. This may result in the formation of crystalline silicon sheets 502 and 504 on the two opposing sides of substrate 506.

In some implementations, the two opposing sides of substrate 506 may be treated to increase their wettability with the molten silicon. Wettability is the ability of a liquid to maintain contact with a solid surface, resulting from intermolecular interactions when the two are brought together. The degree of wettability may be determined by a force balance between adhesive and cohesive forces. Generally, the wettability of silicon overlying a substrate may be strongly dependent on the substrate (e.g., 302). In some implementations, buffer layers may be placed on top of the substrate to improve the wettability of the overlying silicon. For example, silicon nitride (SiN) coatings on substrates may affect the wetting behavior of a silicon melt on a substrate. Silicon nitride coatings may be deposited on a variety of substrates, such as graphite, quartz, etc., using processes, such as chemical vapor deposition (CVD). This deposition may enhance the wetting behavior under certain conditions. Wettability may also depend on the atmosphere (e.g., inert or oxidizing) and the operating pressure inside the furnace (e.g., vacuum or atmospheric or partial pressure). In addition, SiN coatings may serve as release coatings. For example, once a silicon sheet is crystallized onto a substrate with a SiN coating, it is easier to separate the silicon sheet from the substrate for processing. Other than SiN, silicon carbide (SiC) and boron nitride (BN) coatings may also be deposited via CVD and may impact wettability behavior.

In other implementations, to increase the wettability of substrate 506 for molten silicon 508, the surface of the substrate may be treated with chemical etching or physical abrasion to increase surface roughness, for example. The relative temperature between substrate 506 and molten silicon 508 may also be adjusted to increase wettability. The surface free energy (SFE) of the surface of substrate 506 and its polarity may likely also play a role in determining the wettability of the substrate for molten silicon. Wettability, and thus film thickness, may be changed by changing the material used for the substrate (e.g., water won't wet PTFE but will readily wet aluminum foil) or temperature of the liquid (silicon in this case). This will affect viscosity and thickness, which may likely play a role in how the molten silicon adheres to the substrate.

Subsequent steps in the method for fabricating the bi-facial solar cell may include forming p-type regions and n-type regions, such as 312 and 314, in silicon sheets 502 and 504 on both of the two opposing sides of substrate 506. Electrical contacts on the p-type and the n-type regions may then be formed in each of the silicon sheets. Details of this method are described below.

FIG. 6 is a flow diagram of a process 600 for fabricating a bi-facial solar cell, according to some embodiments. For example, the bi-facial solar cell may be the same as or similar to 102, 200, or 300. Process 600, which may be performed by an operator that is human, a computer processor, or a combination of both, may involve steps leading from lunar regolith to an iron-depleted electrolyte produced from an MRE process, for example, to produce a substrate, such as 506. In one implementation, iron-depleted electrolyte may be attained by taking the slag from an iron-producing molten regolith electrolysis process, wherein the iron is mostly removed. Clever choice of regolith harvesting location may also be a possibility, such as choosing a location on the Moon that has an appropriate mixture of compounds for a substrate material. Claimed subject matter, however, is not limited to any particular material compositions, deposition methods, or post-treatment of the materials (e.g., the substrate or materials thereon).

At 602, the operator may support a substrate (e.g., 506) so that both sides of the substrate are at least partially submerged in molten silicon. The melting temperature of the substrate may be greater than the melting temperature of silicon to avoid degradation of the substrate. In some implementations, the two opposing sides of the substrate may be treated to increase their wettability with silicon.

At 604, the operator may control temperature and motion of the molten silicon with respect to the substrate so that a silicon sheet comprising a crystalline form of the molten silicon forms on the two opposing sides of the substrate. As explained above, such controlling of the temperature and the motion of the molten silicon may involve, among other things, maintaining the temperature of the molten silicon to be above the melting temperature of silicon and below a melting temperature of the substrate, and controlling a speed at which the substrate is drawn out of the molten silicon. At 606, the operator may draw the substrate with the crystalline silicon sheets formed thereon upward out of the molten silicon at the controlled speed.

At 608, the operator may form p-type regions and n-type regions in the silicon sheets on both of the two opposing sides of the substrate. The p-type regions and the n-type regions may be arranged side by side with one another on each of the silicon sheets. Forming the p-type regions and the n-type regions may involve forming boron silicate glass and phosphor silicate glass on the silicon sheets on both of the two opposing sides of the substrate and diffusing boron and phosphor dopants from the boron silicate glass and the phosphor silicate glass, respectively, into the silicon sheets. This process may be performed in the natural vacuum of the Moon. On Earth, however, an artificial vacuum may be provided for various parts of the method.

At 610, the operator may form electrical contacts on the p-type and the n-type regions that are in each of the silicon sheets. In some implementations, forming the electrical contacts on the p-type regions and the n-type regions may involve forming openings in the p-type regions and the n-type regions that are on each of the two opposing sides of the substrate and depositing a metal, such as aluminum, into the openings. As mentioned above, the electrical contacts on the p-type regions and the n-type regions on each of the two opposing sides of the substrate may comprise both a positive junction (e.g., positive voltage) and a negative junction (e.g., negative voltage) for an external circuit.

The foregoing description, for purposes of explanation, used specific nomenclature to provide a thorough understanding of the disclosure. However, it will be apparent to one skilled in the art that the specific details are not required in order to practice the systems and methods described herein. The foregoing descriptions of specific embodiments or examples are presented by way of examples for purposes of illustration and description. They are not intended to be exhaustive of or to limit this disclosure to the precise forms described. Many modifications and variations are possible in view of the above teachings. The embodiments or examples are shown and described in order to best explain the principles of this disclosure and practical applications, to thereby enable others skilled in the art to best utilize this disclosure and various embodiments or examples with various modifications as are suited to the particular use contemplated. It is intended that the scope of this disclosure be defined by the following claims and their equivalents.

1-10. (canceled)

11. A bi-facial solar cell comprising:
a substrate having a first surface and a second surface opposite the first surface;
a first silicon sheet on the first surface and a second silicon sheet on the second surface;
p-type regions and n-type regions in each of the first and the second silicon sheets, wherein the p-type regions and the n-type regions are arranged side by side with one another; and
electrical contacts on the p-type and the n-type regions that are in each of the first and the second silicon sheets.

12. The bi-facial solar cell of claim 11, wherein the substrate comprises iron-depleted lunar regolith.

13. The bi-facial solar cell of claim 12, wherein the iron-depleted lunar regolith comprises an electrolyte of a molten electrolysis process.

14. The bi-facial solar cell of claim 11, further comprising:
boron silicate glass on the p-type regions in each of the first and the second silicon sheets; and
phosphor silicate glass on the n-type regions in each of the first and the second silicon sheets.

15. The bi-facial solar cell of claim 11, wherein the electrical contacts on each of the p-type regions and the n-type regions comprise both busbars and fingers.

16. The bi-facial solar cell of claim 11, wherein the electrical contacts on the p-type regions and the n-type regions that are in each of the first and the second silicon sheets comprise both a positive junction and a negative junction for an external circuit.

17. The bi-facial solar cell of claim 11, wherein the melting temperature of the substrate is greater than the melting temperature of silicon.

18. The bi-facial solar cell of claim 11, further comprising p-n junctions between the p-type and the n-type regions, wherein top surfaces of the p-n junctions and the p-type and the n-type regions are configured to be exposed to the sun.

19. The bi-facial solar cell of claim 11, wherein the first and the second silicon sheets are each crystalline.

20. The bi-facial solar cell of claim 11, wherein the substrate is configured to support the bi-facial solar cell on the lunar surface.

21. A bi-facial solar cell comprising:
a substrate having a first surface and a second surface opposite the first surface;
a first silicon sheet on the first surface and a second silicon sheet on the second surface, each silicon sheet comprising a crystalline or polycrystalline silicon layer;
in each of the first and second silicon sheets, alternating p-type and n-type regions arranged laterally with respect to one another to define surface p-n junctions positioned at or near an outer surface of the corresponding silicon sheet;
dopant-containing layers disposed on the p-type and n-type regions to establish the surface p-n junctions; and
electrical contacts coupled to the p-type and n-type regions of each silicon sheet, the electrical contacts of each silicon sheet being interconnected to form respective positive and negative terminals that are independently accessible from opposite sides of the substrate.

22. The bi-facial solar cell of claim 21, wherein the dopant-containing layers comprise boron silicate glass on the p-type regions and phosphor silicate glass on the n-type regions.

23. The bi-facial solar cell of claim 21, wherein each of the first and second silicon sheets has a thickness between 10 μm and 200 μm, and the substrate has a thickness between 2 mm and 10 mm.

24. The bi-facial solar cell of claim 21, wherein the substrate comprises iron-depleted lunar regolith or an electrolyte of a molten electrolysis process.

25. The bi-facial solar cell of claim 21, further comprising an interfacial buffer layer between the substrate and each of the first and second silicon sheets, the buffer layer comprising silicon nitride (SiN), silicon carbide (SiC), or boron nitride (BN).

26. The bi-facial solar cell of claim 21, further comprising coverglass disposed over outward-facing surfaces of the first and second silicon sheets, the coverglass comprising a transparent silicate derived from lunar in-situ resources.

27. The bi-facial solar cell of claim 21, wherein the p-type and n-type regions in each silicon sheet form laterally alternating stripes extending across the sheet, and top surfaces of the p-n junctions are substantially coplanar with outer surfaces of the silicon sheets.

28. The bi-facial solar cell of claim 21, wherein the electrical contacts on each silicon sheet comprise a grid of busbars and fingers configured to reduce optical shadowing of the silicon sheet.

29. The bi-facial solar cell of claim 21, wherein the substrate includes a portion extending beyond the perimeters of the first and second silicon sheets to provide a mechanical support or mounting interface for the solar cell.

30. The bi-facial solar cell of claim 21, wherein each of the first and second silicon sheets comprises n-type silicon, and the n-type regions are more heavily doped than a background doping concentration of the corresponding silicon sheet.
